(19) United States
(12) Patent Application Publication
(10) Pub. No.: US 2024/0175125 A1
(43) Pub. Date: May 30, 2024

(54) SUBSTRATE PROCESSING APPARATUS AND SUBSTRATE PROCESSING METHOD

(71) Applicant: TOKYO ELECTRON LIMITED, Tokyo (JP)

(72) Inventor: Sung Duk SON, Gyeonggi-do (KR)

(21) Appl. No.: 18/523,060

(22) Filed: Nov. 29, 2023

(30) Foreign Application Priority Data
Nov. 30, 2022 (JP) 2022-192041

(51) Int. Cl. C23C 16/44; C23C 16/455; C23C 16/50; H01J 37/32

(52) U.S. Cl. CPC C23C 16/4405; C23C 16/45563; C23C 16/50; H01J 37/3244; H01J 37/32834; H01J 37/32862; H01J 2237/1825; H01J 2237/334

(57) ABSTRACT

A substrate processing apparatus includes: a processing container configured to be depressurized; a plasma box including an interior, which communicates with an interior of the processing container, and configured such that plasma is generated in the interior of the plasma box; a first gas nozzle installed in the processing container and into which a cleaning gas is introduced; and a second gas nozzle installed in the plasma box and configured such that an interior of the second gas nozzle is adjusted to have a negative pressure with respect to the interior of the processing container.

### CROSS-REFERENCE TO RELATED APPLICATION

This application is based upon and claims the benefit of priority from Japanese Patent Application No. 2022-192041, filed on Nov. 30, 2022, the entire contents of which are incorporated herein by reference.

### TECHNICAL FIELD

The present disclosure relates to a substrate processing apparatus and a substrate processing method.

### BACKGROUND

Techniques are known for removing deposits attached to a gas nozzle or a plasma generator included in a substrate processing apparatus (see, for example, Patent Documents 1 and 2).

### PRIOR ART DOCUMENTS

### Patent Documents

Patent Document 1: Japanese Patent Laid-Open Publication No. 2009-094383
Patent Document 2: Japanese Patent Laid-Open Publication No. 2018-186235

### SUMMARY

According to one embodiment of the present disclosure, there is provided a substrate processing apparatus including: a processing container configured to be depressurized; a plasma box including an interior, which communicates with an interior of the processing container, and configured such that plasma is generated in the interior of the plasma box; a first gas nozzle installed in the processing container and into which a cleaning gas is introduced; and a second gas nozzle installed in the plasma box and configured such that an interior of the second gas nozzle is adjusted to have a negative pressure with respect to the interior of the processing container.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic vertical cross-sectional view illustrating a substrate processing apparatus according to an embodiment.

FIG. 2 is a schematic horizontal cross-sectional view illustrating the substrate processing apparatus according to the embodiment.

FIG. 3 is a view illustrating a gas system in the substrate processing apparatus of FIG. 1.

FIG. 4 is a view illustrating the flows of gases in a film forming process.

FIG. 5 is a view illustrating the flows of gases in a plasma box cleaning process.

FIG. 6 is a view illustrating the flows of gases in a plasma box cleaning process.

FIG. 7 is a view illustrating the flows of gases in a chamber cleaning process.

FIG. 8 is a flowchart illustrating a substrate processing method according to a first example of the embodiment.

FIG. 9 is a flowchart illustrating a substrate processing method according to a second example of the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting exemplary embodiments of the present disclosure will be described with reference to the accompanying drawings. In all the accompanying drawings, the same or corresponding members or components will be denoted by the same or corresponding reference numerals, and redundant descriptions will be omitted.

### [Substrate Processing Apparatus]

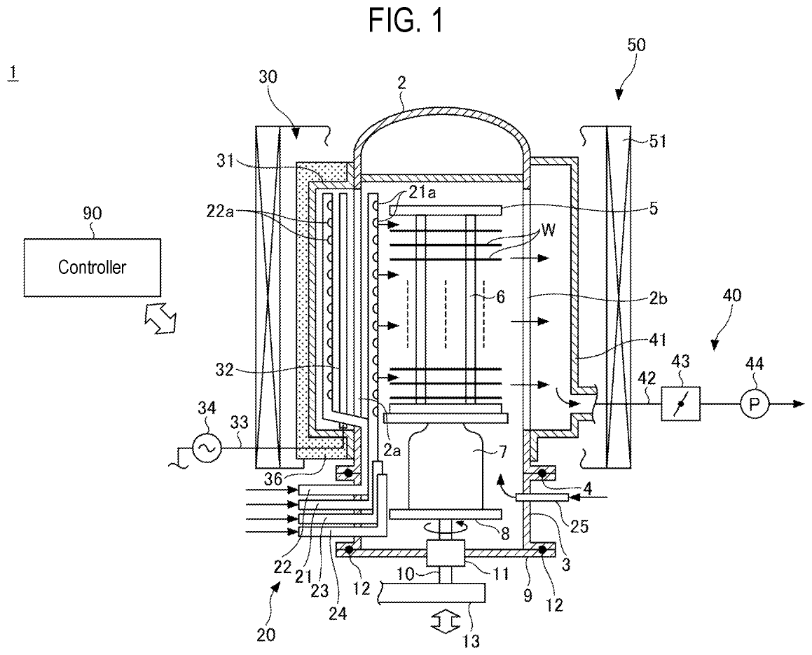

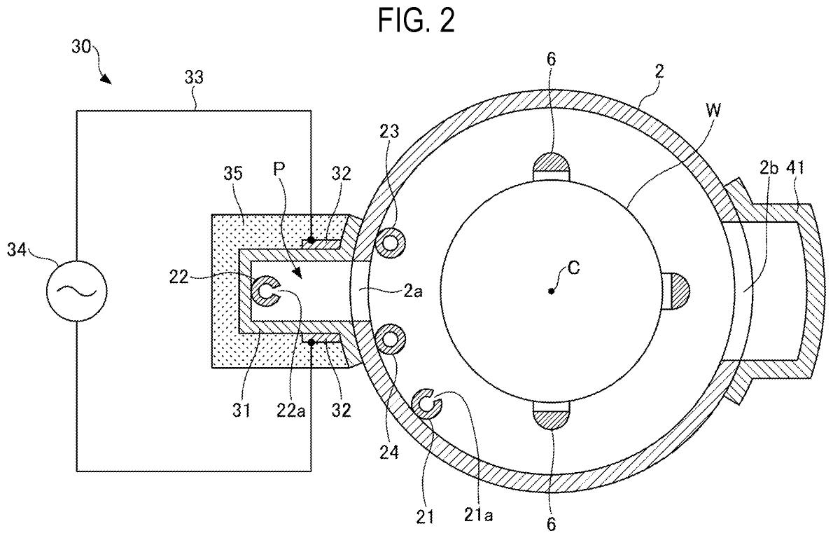

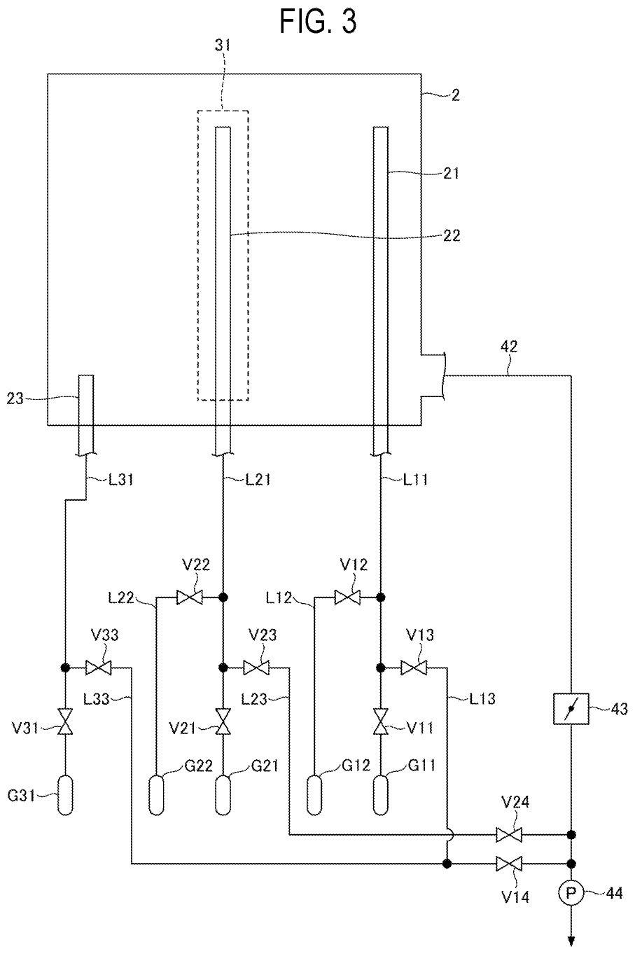

A substrate processing apparatus 1 according to an embodiment will be described with reference to FIGS. 1 to 3. FIG. 1 is a schematic vertical cross-sectional view illustrating the substrate processing apparatus 1 according to the embodiment. FIG. 2 is a schematic horizontal cross-sectional view of the substrate processing apparatus 1 according to the embodiment. FIG. 3 is a view illustrating a gas system in the substrate processing apparatus 1 of FIG. 1.

The substrate processing apparatus 1 includes a processing container 2, a gas supplier 20, a plasma generator 30, an exhauster 40, a heating portion 50, and a controller 90.

The interior of the processing container 2 can be depressurized. The processing container 2 has a cylindrical shape with a ceiling and an open bottom end. The processing container 2 is made of, for example, quartz. A cylindrical manifold 3 is connected to the opening at the lower end of the processing container 2 via a sealing member 4. The manifold 3 is made of a metal material such as stainless steel. The sealing member 4 is, for example, an O-ring.

The manifold 3 supports the lower end of the processing container 2. A boat 5 holds substrates W horizontally in the form of a shelf. The number of substrates W is, for example, 25 to 200. The boat 5 is inserted into the processing container 2 from below the manifold 3. The boat 5 is made of, for example, quartz. The boat 5 has rods 6. The boat 5 holds the substrates W by grooves (not illustrated) formed in each rod 6. The number of rods 6 is, for example, three.

The boat 5 is placed on a table 8 via a heat insulating cylinder 7 made of quartz. The table 8 is supported on a rotary shaft 10. The rotary shaft 10 penetrates a lid 9 that opens and closes an opening at the lower end of the manifold 3. The lid 9 is made of a metal material such as stainless steel.

A magnetic fluid seal 11 is provided in the penetrating portion of the rotary shaft 10. The magnetic fluid seal 11 airtightly seals and rotatably supports the rotary shaft 10. A sealing member 12 is provided between the peripheral portion of the lid 9 and the lower end of the manifold 3 to maintain airtightness within the processing container 2. The sealing member 12 is, for example, an O-ring.

The rotary shaft 10 is attached to the tip of an arm 13 supported by a lifting mechanism (not illustrated) such as a boat elevator. The boat 5, the heat-insulating tube 7, the table 8, the lid 9, and the rotary shaft 10 are integrally raised and lowered, and are inserted into and removed from the interior of the processing container 2.

The processing container 2 has an opening 2a in a portion of the side wall. The opening 2a is formed to be elongated in the vertical direction to cover all the substrates W held in the boat 5 in the vertical direction. The processing container 2 has an exhaust port 2b on a side wall opposite to the opening 2a. The exhaust port 2b is vertically elongated to correspond to the boat 5.

The gas supplier 20 has gas nozzles 21 to 25. Each of the gas nozzles 21 to 25 is made of, for example, quartz.

The gas nozzle 21 has an L-shape that penetrates the side wall of the manifold 3 inwardly, is bent upward, and extends vertically. The vertical portion of the gas nozzle 21 is provided inside the processing container 2. Gas holes 21a are formed in the vertical portion of the gas nozzle 21 along the vertical direction. The gas holes 21a are formed over a vertical length corresponding to, for example, a range in which the substrate are supported in the boat 5. Each gas hole 21a horizontally ejects a gas introduced into the gas nozzle 21.

A gas supply flow path L11 is connected to the gas nozzle 21. The gas supply flow path L11 is provided with an opening/closing valve V11 and a source G11 of a first reaction gas in order from the gas nozzle 21 side. The first reaction gas may be, for example, a silicon-containing gas such as dichlorosilane (DCS) or hexachlorodisilane (HCDS). When the opening/closing valve V11 is opened, the first reaction gas from the source G11 is introduced into the gas nozzle 21 through the gas supply flow path L11.

A gas supply flow path L12 is connected to the gas supply flow path L11 between the gas nozzle 21 and the opening/closing valve V11. The gas supply flow path L12 is provided with an opening/closing valve V12 and a source G12 of a cleaning gas in order from the gas nozzle 21 side. The cleaning gas may be, for example, fluorine gas (F₂). When the opening/closing valve V12 is opened, the cleaning gas from the source G12 is introduced into the gas nozzle 21 through the gas supply flow paths L12 and L11. The gas supply flow path L12 may be provided with a source of an inert gas (not illustrated). The inert gas may be, for example, nitrogen gas (N₂).

A nozzle exhaust flow path L13 is connected to the gas supply flow path L11 between the gas nozzle 21 and the opening/closing valve V11. The nozzle exhaust flow path L13 is connected to the exhaust pipe 42 between a pressure control valve 43 and a vacuum pump 44. Opening/closing valves V13 and V14 are provided in the nozzle exhaust flow path L13. When the opening/closing valves V13 and V14 are opened, the vacuum pump 44 exhausts the interior of the gas nozzle 21, the gas supply flow path L11, and the nozzle exhaust flow path L13. For example, when the opening/closing valves V13 and V14 are opened while the pressure control valve 43 is closed, the interior of the processing container 2 will not be exhausted via the exhaust pipe 42, and the interior of the gas nozzle 21 is exhausted via the nozzle exhaust flow path L13. As a result, the pressure inside the gas nozzle 21 is adjusted to have a negative pressure with respect to the interior of the processing container 2. In this way, it is possible to adjust the interior of the gas nozzle 21 to have a negative pressure with respect to the interior of the processing container 2.

The gas nozzle 22 has an L-shape that penetrates the side wall of the manifold 3 inwardly, is bent upward, and extends vertically. The vertical portion of the gas nozzle 22 is provided in a plasma generation space P. Gas holes 22a are provided in the vertical portion of the gas nozzle 22 along the vertical direction. The gas holes 22a are provided over a vertical length corresponding to, for example, a range in which the substrate are supported in the boat 5. Each gas hole 22a horizontally ejects a gas introduced into the gas nozzle 22.

A gas supply flow path L21 is connected to the gas nozzle 22. The gas supply flow path L21 is provided with an opening/closing valve V21 and a source G21 of a second reaction gas in order from the gas nozzle 22 side. The second reaction gas is a gas that reacts with the first reaction gas to produce a reaction product. The second reaction gas may be, for example, ammonia gas (NH₃). When the opening/closing valve V21 is opened, the second reaction gas from the source G21 is introduced into the gas nozzle 22 through the gas supply flow path L21.

A gas supply flow path L22 is connected to the gas supply flow path L21 between the gas nozzle 22 and the opening/closing valve V21. The gas supply flow path L22 is provided with an opening/closing valve V22 and a source G22 of an inert gas in order from the gas nozzle 22 side. The inert gas is, for example, nitrogen gas. When the opening/closing valve V22 is opened, the inert gas from the source G22 is introduced into the gas nozzle 22 through the gas supply flow paths L22 and L21.

A nozzle exhaust flow path L23 is connected to the gas supply flow path L21 between the gas nozzle 22 and the opening/closing valve V21. The nozzle exhaust flow path L23 is connected to the exhaust pipe 42 between the pressure control valve 43 and the vacuum pump 44. Opening/closing valves V23 and V24 are provided in the nozzle exhaust flow path L23. When the opening/closing valves V23 and V24 are opened, the vacuum pump 44 exhausts the interior of the gas nozzle 22, the gas supply flow path L21, and the nozzle exhaust flow path L23. For example, when the opening/closing valves V23 and V24 are opened while the pressure control valve 43 is closed, the interior of the processing container 2 will not be exhausted via the exhaust pipe 42, and the interior of the gas nozzle 22 is exhausted via the nozzle exhaust flow path L23. As a result, the pressure inside the gas nozzle 22 is adjusted to have a negative pressure with respect to the interior of the processing container 2. In this way, it is possible to adjust the interior of the gas nozzle 22 to have a negative pressure with respect to the interior of the processing container 2.

The gas nozzle 23 has an L-shape that penetrates the side wall of the manifold 3 inwardly, is bent upward, and extends vertically. The upper end of the gas nozzle 23 is located below the lower end of the boat 5. The gas nozzle 23 has an opening at its upper end. The gas nozzle 23 ejects the gas, introduced into the gas nozzle 23, upward from the opening at its upper end.

A gas supply flow path L31 is connected to the gas nozzle 23. The gas supply flow path L31 is provided with an opening/closing valve V31 and a source G31 of a cleaning gas in this order from the gas nozzle 23 side. The cleaning gas may be, for example, fluorine gas. When the opening/closing valve V31 is opened, the cleaning gas from the source G31 is introduced into the gas nozzle 23 through the gas supply flow path L31.

A nozzle exhaust flow path L33 is connected to the gas supply flow path L31 between the gas nozzle 23 and the opening/closing valve V31. The nozzle exhaust flow path L33 is connected to the nozzle exhaust flow path L13. An opening/closing valve V33 is provided in the nozzle exhaust flow path L33. When the opening/closing valves V33 and V14 are opened, the interior of the gas nozzle 23, the gas supply flow path L31, and the nozzle exhaust flow path L33 are exhausted. For example, when the opening/closing valves V33 and V14 are opened while the pressure control valve 43 is closed, the interior of the processing container 2 will not be exhausted via the exhaust pipe 42, and the interior of the gas nozzle 23 is exhausted via the nozzle exhaust flow path L33. As a result, the pressure inside the gas nozzle 23 is adjusted to have a negative pressure with respect to the interior of the processing container 2. In this way, it is possible to adjust the interior of the gas nozzle 23 to have a negative pressure with respect to the interior of the processing container 2.

The gas nozzle 24 has an L-shape that penetrates the side wall of the manifold 3 inwardly, is bent upward, and extends vertically. In FIG. 3, illustration of the gas nozzle 24 is omitted. The upper end of the gas nozzle 24 is located below the lower end of the boat 5. The gas nozzle 24 has an opening at its upper end. The gas nozzle 24 ejects the gas, introduced into the gas nozzle 24, upward from the opening at its upper end. A cleaning gas such as hydrogen fluoride gas (HF) is introduced into the gas nozzle 24.

The gas nozzle 25 has a straight pipe shape that extends horizontally through the side wall of the manifold 3. The tip of the gas nozzle 25 is provided inside the processing container 2. The gas nozzle 25 has an opening at its tip. The gas nozzle 25 ejects the gas introduced into the gas nozzle 25 horizontally from the opening at its tip. An inert gas such as nitrogen gas is introduced into the gas nozzle 25.

The plasma generator 30 includes a plasma box 31, a pair of electrodes 32, a feeder line 33, an RF power source 34, and an insulating cover 35.

The plasma box 31 is substantially U-shaped in horizontal cross section. The plasma box 31 is airtightly installed to the outer wall of the processing container 2 to cover the opening 2a. The plasma box 31 extends vertically along the side wall of the processing container 2. The plasma box 31 forms a plasma generation space P therein. The plasma generation space P communicates with the interior of the processing container 2. The plasma box 31 is made of, for example, quartz.

The pair of electrodes 32 each have an elongated shape, and are disposed opposite to each other along the vertical direction on the outer surfaces of opposite side walls of the plasma box 31. A feeder line 33 is connected to each electrode 32.

The feeder line 33 electrically connects each electrode 32 to the RF power source 34.

The RF power source 34 is electrically connected to each electrode 32 via the feeder line 33. The RF power source 34 supplies the pair of electrodes 32 with RF power at a predetermined frequency. As a result, plasma is generated in the plasma generation space P from the second reaction gas ejected from the gas nozzle 22. The predetermined frequency is, for example, 13.56 MHz.

The insulating cover 35 is installed to the outside of the plasma box 31 to cover the plasma box 31. A coolant passage (not illustrated) through which coolant flows may be provided inside the insulating cover 35. In this case, each electrode 32 can be cooled. A shield (not illustrated) may be provided inside the insulating cover 35 to cover the electrodes 32. The shield is formed of a good conductor such as metal and is grounded.

The exhauster 40 includes an exhaust port cover 41, an exhaust pipe 42, a pressure control valve 43, and a vacuum pump 44.

The exhaust port cover 41 is substantially U-shaped in horizontal cross section. The exhaust port cover 41 is airtightly installed to the outer wall of the processing container 2 to cover the exhaust port 2b. The exhaust port cover 41 extends vertically along the side wall of the processing container 2.

The exhaust pipe 42 is provided at the bottom of the exhaust port cover 41. The exhaust pipe 42 is provided with the pressure control valve 43, and the vacuum pump 44 in order from the processing container 2 side.

The pressure control valve 43 controls the pressure inside the processing container 2.

The vacuum pump 44 exhausts the interior of the processing container 2 via the exhaust pipe 42. The vacuum pump 44 exhausts the interior of the gas nozzle 21 via the nozzle exhaust flow path L13. The vacuum pump 44 exhausts the interior of the gas nozzle 22 via the nozzle exhaust flow path L23. The vacuum pump 44 exhausts the interior of the gas nozzle 23 via the nozzle exhaust flow path L33.

The heating portion 50 includes a heater 51. The heater 51 has a cylindrical shape with a ceiling that surrounds the processing container 2 on the outside in the radial direction of the processing container 2 and covers the ceiling of the processing container 2. The heater 51 heats each substrate W accommodated in the processing container 2 by heating the side periphery and ceiling of the processing container 2.

The controller 90 controls the operation of each component of the substrate processing apparatus 1. The controller 90 may be, for example, a computer. A computer program for operating each component of the substrate processing apparatus 1 is stored in a storage medium. The storage medium may be a flexible disk, a compact disk, a hard disk, flash memory, a DVD, or the like.

### [Various Processes]

Various processes performed in the substrate processing apparatus 1 will be explained.

### (Film Forming Process)

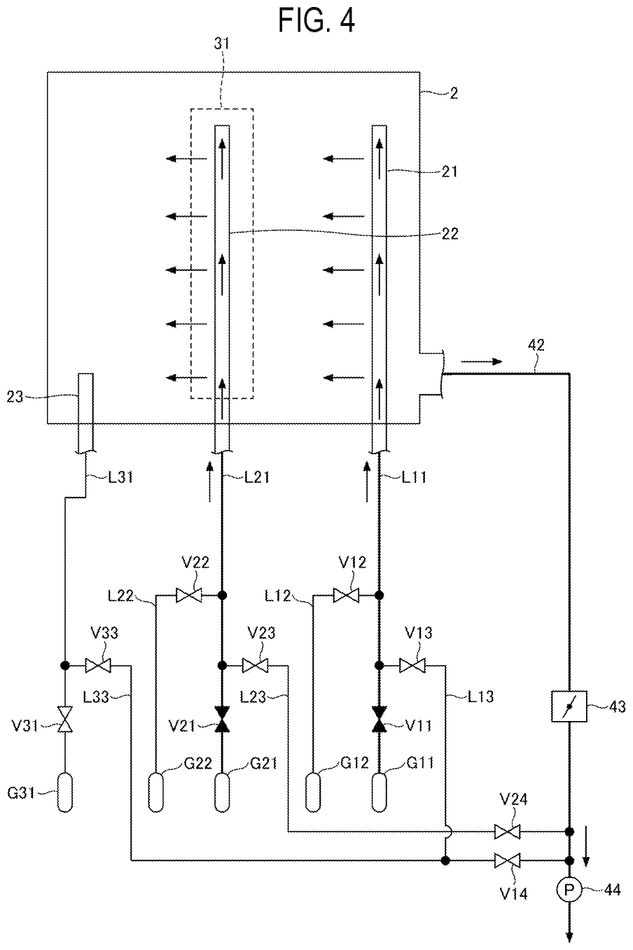

With reference to FIG. 4, the flows of gases when performing a process of forming a film on a substrate W (hereinafter, referred to as a “film forming process”) in the processing container 2 will be described. FIG. 4 is a view illustrates the flows of gases in a film forming process. In FIG. 4, the opening/closing valves in the opened state are indicated in black, and the opening/closing valves in the closed state are indicated in white. In FIG. 4, the flow paths through which the gases flow are indicated by thick solid lines, and the direction in which the gases flow are indicated by arrows.

The film forming process is performed, for example, in a state where a boat 5 holding substrates W is accommodated in the processing container 2. In the film forming process, the opening/closing valves V11 and V21 and the pressure control valve 43 are opened, and the opening/closing valves V12, V13, V14, V22, V23, V24, V31, and V33 are closed. As a result, the first reaction gas is ejected from the gas nozzle 21 into the processing container 2, and the second reaction gas is ejected from the gas nozzle 22 into the plasma generation space P. In the film forming process, RF power is supplied from the RF power source 34 to the pair of electrodes 32. As a result, plasma is generated from the second reaction gas in the plasma generation space P.

In the film forming process, a film is formed on the substrates W by a reaction product generated by the reaction between the first reaction gas and the second reaction gas. In the film forming process, the film of the reaction product is also deposited on the inner wall of the processing container 2, inside the gas nozzles 21 and 22, and inside the plasma box 31.

In addition, in the film forming process, the supply of the first reaction gas from the gas nozzle 21, and the supply of the second reaction gas from the gas nozzle 22 and the supply of RF power from the RF power source 34 may be alternately performed with the supply of an inert gas interposed therebetween.

### (Plasma Box Cleaning Process)

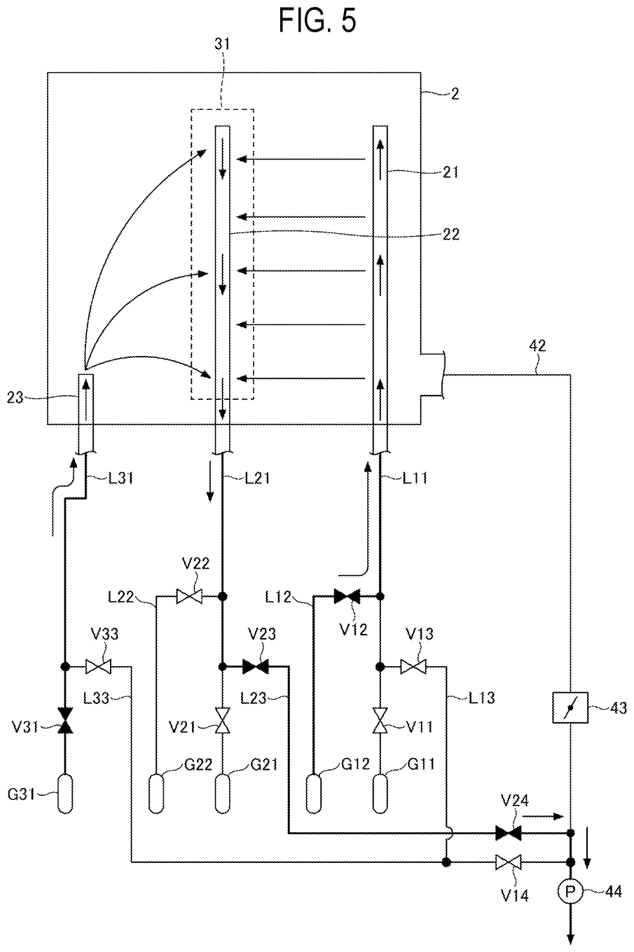

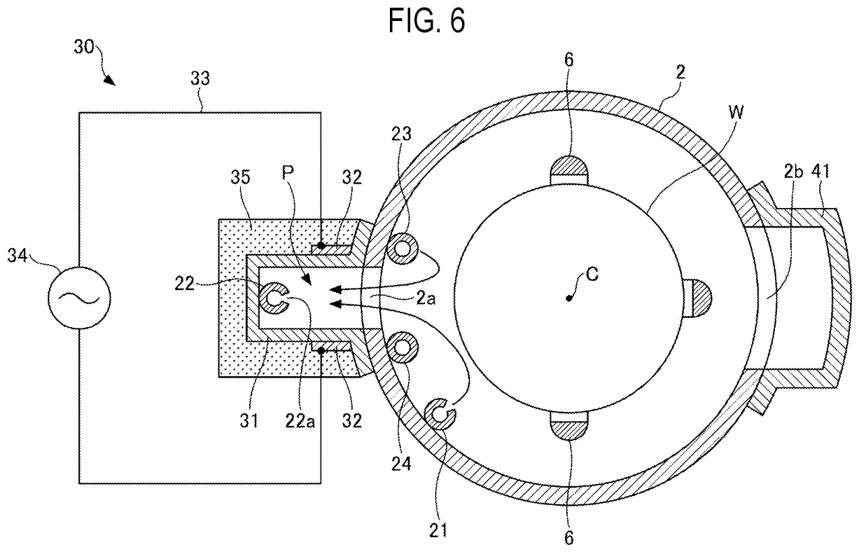

With reference to FIGS. 5 and 6, the flows of gases when performing a process of removing deposits inside the plasma box 31 (hereinafter, referred to as a “plasma box cleaning process”) will be described. FIGS. 5 and 6 are views illustrating the flows of gases in a plasma box cleaning process. In FIG. 5, the opening/closing valves in the opened state are indicated in black, and the opening/closing valves in the closed state are indicated in white. In FIG. 5, the flow paths through which the gases flows are indicate by thick solid lines. In FIGS. 5 and 6, the directions in which the gases flow are indicated by arrows.

The plasma box cleaning process is performed, for example, in a state in which an empty boat 5 that does not hold the substrates W is accommodated in the processing container 2. In this case, when removing the deposits inside the processing container 2, the deposits deposited on the empty boat 5 can also be removed. When the deposits on the boat 5 are not removed, the plasma box cleaning process may be performed in a state in which the boat 5 is not accommodated in the processing container 2.

In the plasma box cleaning process, the opening/closing valves V12, V23, V24, and V31 are opened, and the opening/closing valves V11, V13, V14, V21, V22, and V33, and the pressure control valve 43 are closed.

Specifically, in the state in which the interior of the processing container 2 is depressurized and all the opening/closing valves and the pressure control valve 43 are closed, the opening/closing valve V24 is first opened. Subsequently, the opening/closing valve V23 is opened. As a result, the interior of the gas nozzle 22 is exhausted by the vacuum pump 44, and the interior of the plasma box 31 has a negative pressure with respect to the interior of the processing container 2. Subsequently, the opening/closing valves V12 and V31 are opened, and cleaning gases are ejected from the gas nozzles 21 and 23 into the processing container 2. This forms the flows in which the cleaning gases ejected from the gas nozzles 21 and 23 into the processing container 2 are drawn into the gas nozzle 22. Due to these flows of the cleaning gases, the deposits inside the plasma box 31 can be effectively removed with a small flow rate of cleaning gas. As a result, the generation of particles due to deposits inside the plasma box 31 can be suppressed, and the maintenance cycle of the substrate processing apparatus 1 can be extended.

In the plasma box cleaning process, a cleaning gas is ejected into the processing container 2 from the gas holes 21a of the gas nozzle 21, and the ejected cleaning gas is drawn into the gas holes 22a of the gas nozzle 22. In this case, the horizontal flow of the cleaning gas is formed from the gas nozzle 21 toward the gas nozzle 22. Therefore, deposits can be removed evenly in the vertical direction inside the plasma box 31.

In addition, in the plasma box cleaning process, a cleaning gas may be ejected from only one of the gas nozzle 21 and the gas nozzle 23. In addition, in the plasma box cleaning process, a cleaning gas may be ejected from the gas nozzle 24.

However, when the interior of the gas nozzle 22 is not exhausted, a flow in which the cleaning gas is drawn into the gas nozzle 22 is not formed, so that the deposits inside the plasma box 31 tend to remain without being removed. When removing the deposits remaining in the plasma box 31, a large flow rate of cleaning gas is required.

It is also conceivable to eject a cleaning gas from the gas nozzle 22 into the plasma generation space P to remove the deposits inside the plasma box 31. In this case, since the cleaning gas ejected horizontally from the gas holes 22a of the gas nozzle 22 tends to flow toward the exhaust port 2b of the processing container 2, the deposits inside the plasma box 31 are difficult to remove.

### (Chamber Cleaning Process)

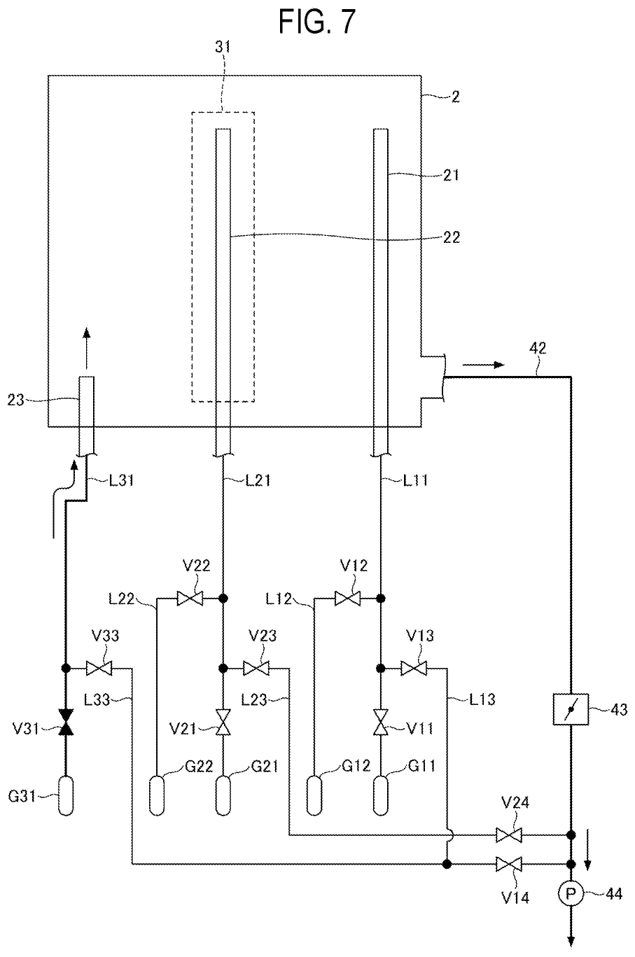

With reference to FIG. 7, the flows of gases when performing a process for removing deposits in the processing container 2 (hereinafter, referred to as a “chamber cleaning process”) will be described. FIG. 7 is a view illustrating the flows of gases in a chamber cleaning process. In FIG. 7, the opening/closing valve in the opened state is indicated in black, and the opening/closing valves in the closed state are indicated in white. In FIG. 7, the flow paths through which gases flow are indicated by thick solid lines, and the direction in which the gases flow are indicated by arrows.

The chamber cleaning process is performed, for example, in a state in which an empty boat 5 that does not hold the substrates W is accommodated in the processing container 2. In this case, when removing the deposits inside the processing container 2, the deposits deposited on the empty boat 5 can also be removed. When the deposits on the boat 5 are not removed, the chamber cleaning process may be performed in a state in which the boat 5 is not accommodated in the processing container 2.

In the chamber cleaning process, the opening/closing valve V31 and the pressure control valve 43 are opened, and the opening/closing valves V11, V12, V13, V14, V21, V22, V23, V24, and V33 are closed. As a result, the cleaning gas is ejected from the gas nozzle 23 into the processing container 2, and the interior of the processing container 2 is exhausted by the vacuum pump 44.

In the chamber cleaning process, the deposits inside the processing container 2 and on the empty boat 5 are removed. In the chamber cleaning process, since the interior of the gas nozzle 22 is not exhausted, cleaning gas is not drawn into the plasma box 31. For this reason, the deposits inside the plasma box 31 are difficult to remove.

In the chamber cleaning process, cleaning gas may be ejected from the gas nozzle 21 into the processing container 2. However, from the viewpoint of suppressing corrosion inside the gas nozzle 21 due to a prolonged exposure time of the interior of the gas nozzle 21 to the cleaning gas, it is preferable not to eject the cleaning gas from the gas nozzle 21 into the processing container 2.

In the chamber cleaning process, cleaning gas may be ejected from the gas nozzle 24 into the processing container 2.

### [Substrate Processing Method]

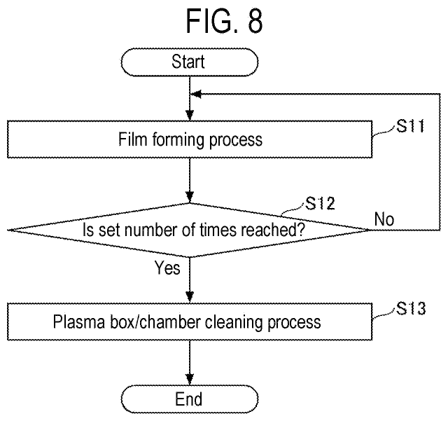

With reference to FIG. 8, a substrate processing method according to a first example of the embodiment will be described. FIG. 8 is a flowchart illustrating the substrate processing method according to the first example of the embodiment. Hereinafter, the substrate processing method according to the first example of the embodiment will be described by taking as an example the case where the substrate processing method is implemented in the above-described substrate processing apparatus 1.

As illustrated in FIG. 8, the substrate processing method according to the first example of the embodiment includes a step S11 of performing a film formation process, a step S12 of determining, and a step S13 of performing a plasma box cleaning process and a chamber cleaning process.

In step S11, first, the controller 90 controls the operation of each component of the substrate processing apparatus 1 such that a boat 5 holding substrates W is accommodated in the processing container 2. Subsequently, the controller 90 opens the pressure control valve 43 and exhausts the interior of the processing container 2 to depressurize the interior of the processing container 2. Subsequently, the controller 90 controls the heating portion 50 such that the interior of the processing container 2 has a desired set temperature, and controls the pressure control valve 43 such that the interior of the processing container 2 has a desired pressure. Subsequently, the controller 90 controls the operation of each component of the substrate processing apparatus 1 to perform the above-described film forming process. Next, the controller 90 supplies an inert gas into the processing container 2 to purge the interior of the processing container 2, and then controls the operation of each component of the substrate processing apparatus 1 to increase the pressure inside the processing container 2 to atmospheric pressure. Finally, the controller 90 controls the operation of each component of the substrate processing apparatus 1 to carry the boat 5 out of the processing container 2.

Step S12 is performed after step S11. In step S12, the controller 90 determines whether step S11 has been performed a set number of times. When the number of times of performance has not reached the set number of times (“NO” in step S12), the controller 90 controls the operation of each component of the substrate processing apparatus 1 to perform step S11 again. When the number of times of performance has reached the set number of times (“YES” in step S12), the controller 90 advances the process to step S13. In this way, step S11 is repeated until the number of times of performance reaches the set number of times.

Step S13 is performed after step S12. In step S13, first, the controller 90 controls the operation of each component of the substrate processing apparatus 1 such that an empty boat 5 is accommodated in the processing container 2. Subsequently, the controller 90 opens the pressure control valve 43 and exhausts the interior of the processing container 2 to depressurize the same. Subsequently, the controller 90 controls the heating portion 50 such that the interior of the processing container 2 has a desired set temperature, and controls the pressure control valve 43 such that the interior of the processing container 2 has a desired pressure. Subsequently, the control 90 controls the operations of each component of the substrate processing apparatus 1 to perform the above-described plasma box cleaning process and chamber cleaning process in this order. The plasma box cleaning process is performed, for example, under a condition where the flow rate of the cleaning gas ejected into the processing container 2 is smaller than that in the chamber cleaning process. Next, the controller 90 supplies an inert gas into the processing container 2 to purge the interior of the processing container 2, and then controls the operation of each component of the substrate processing apparatus 1 to increase the pressure inside the processing container 2 to atmospheric pressure. Finally, the controller 90 controls the operation of each component of the substrate processing apparatus 1 to carry the boat 5 out of the processing container 2. With the above, the substrate processing method according to the first example of the embodiment is completed.

As described above, in the substrate processing method according to the first example of the embodiment, the plasma box cleaning process and the chamber cleaning process are performed once each time the number of times of performing the film forming process reaches the set number of times.

In the substrate processing method according to the first example of the embodiment, the case where the chamber cleaning process is performed without changing the temperature and pressure inside the processing container 2 after the plasma box cleaning process in step S13 has been described, but the present disclosure is not limited thereto. For example, after the plasma box cleaning process, the chamber cleaning process may be performed after changing at least one of the temperature or pressure inside the processing container 2.

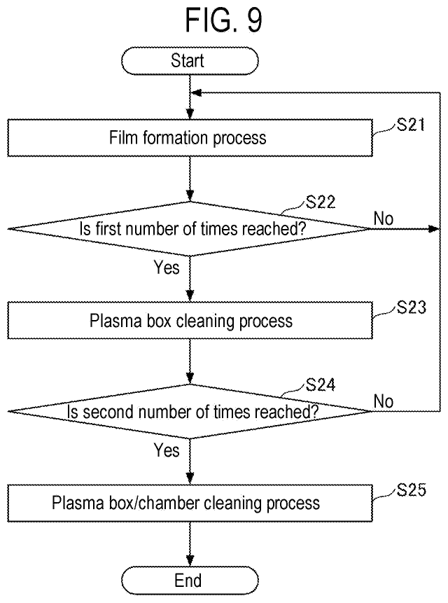

With reference to FIG. 9, a substrate processing method according to a second example of the embodiment will be described. FIG. 9 is a flowchart illustrating the substrate processing method according to the second example of the embodiment. Hereinafter, the substrate processing method according to the second example of the embodiment will be described by taking as an example the case where the substrate processing method is implemented in the above-described substrate processing apparatus 1.

As illustrated in FIG. 9, the substrate processing method according to the second example of the embodiment includes a step S21 of performing a film forming process, a step S22 of determining, a step S23 of performing a plasma box cleaning process, a step S24 of determining, and a step S25 of performing a plasma box cleaning process and a chamber cleaning process.

Step S21 may be the same as step S11.

Step S22 is performed after step S21. In step S22, the controller 90 determines whether step S21 has been performed a first number of times. When the number of times of performance has not reached the first number of times (“NO” in step S22), the controller 90 controls the operation of each component of the substrate processing apparatus 1 to perform step S21 again. When the number of times of performance has reached the first number of times (“YES” in step S22), the controller 90 advances the process to step S23. In this way, step S21 is repeated until the number of times of performance reaches the first number of times.

Step S23 is performed after step S22. In step S23, first, the controller 90 controls the operation of each component of the substrate processing apparatus 1 such that an empty boat 5 is accommodated in the processing container 2. Subsequently, the controller 90 opens the pressure control valve 43 and exhausts the interior of the processing container 2 to depressurize the same. Subsequently, the controller 90 controls the heating portion 50 such that the interior of the processing container 2 has a desired set temperature, and controls the pressure control valve 43 such that the interior of the processing container 2 has a desired pressure. Subsequently, the controller 90 controls the operation of each component of the substrate processing apparatus 1 to perform the above-described plasma box cleaning process. Next, the controller 90 supplies an inert gas into the processing container 2 to purge the interior of the processing container 2, and then controls the operation of each component of the substrate processing apparatus 1 to increase the pressure inside the processing container 2 to atmospheric pressure. Finally, the controller 90 controls the operation of each component of the substrate processing apparatus 1 to carry the boat 5 out of the processing container 2.

Step S24 is performed after step S23. In step S24, the controller 90 determines whether steps S21 to S23 have been performed a second number of times. When the number of times of performance has not reached the second number of times (“NO” in step S24), the controller 90 controls the operation of each component of the substrate processing apparatus 1 to perform steps S21 to S23 again. When the number of times of performance has reached the second number of times (“YES” in step S24), the controller 90 advances the process to step S25. In this way, steps S21 to S23 are repeated until the number of times of performance reaches the second number of times.

Step S25 is performed after step S24. Step S25 may be the same as step S13.

As described above, in the substrate processing method according to the second example of the embodiment, the plasma box cleaning process is performed once each time the number of times of performing the film forming process reaches the first number of times. In addition, the plasma box cleaning process and the chamber cleaning process are performed once each time the number of times the plasma box cleaning process is performed reaches the second number of times.

In the above-described embodiment, the gas nozzle 21 is an example of the first gas nozzle, the gas nozzle 22 is an example of the second gas nozzle, and the gas nozzle 23 is an example of the third gas nozzle.

It is to be considered that the embodiments disclosed herein are exemplary in all respects and not restrictive. Various types of omissions, replacements, and changes may be made to the above-described embodiment without departing from the scope and spirit of the appended claims.

According to the present disclosure, deposits inside a plasma box can be effectively removed.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a processing container configured to be depressurized;
a plasma box including an interior, which communicates with an interior of the processing container, and configured such that plasma is generated in the interior of the plasma box;
a first gas nozzle installed in the processing container and into which a cleaning gas is introduced; and
a second gas nozzle installed in the plasma box and configured such that an interior of the second gas nozzle is adjusted to have a negative pressure with respect to the interior of the processing container.

2. The substrate processing apparatus of claim 1, further comprising:
an exhaust pipe connected to the processing container and configured to exhaust the interior of the processing container; and
a nozzle exhaust flow path connected to the second gas nozzle and the exhaust pipe and configured to exhaust the interior of the second gas nozzle without passing through the interior of the processing container.

3. The substrate processing apparatus of claim 2, further comprising:
a pressure control valve and a vacuum pump, which are installed in the exhaust pipe,
wherein the nozzle exhaust flow path is connected to the exhaust pipe between the pressure control valve and the vacuum pump.

4. The substrate processing apparatus of claim 1, wherein a first reaction gas is introduced into the first gas nozzle, and
a second reaction gas that reacts with the first reaction gas is introduced into the second gas nozzle.

5. The substrate processing apparatus of claim 1, wherein the first gas nozzle and the second gas nozzle each have gas holes configured to eject gas horizontally.

6. The substrate processing apparatus of claim 5, further comprising:
a third gas nozzle installed inside the processing container and into which the cleaning gas is introduced,
wherein the third gas nozzle has an opening configured to eject gas upward.

7. The substrate processing apparatus of claim 1, further comprising:
a controller configured to control the substrate processing apparatus to supply the cleaning gas from the first gas nozzle into the processing container in a state in which the interior of the second gas nozzle is adjusted to have the negative pressure.

8. A substrate processing method implemented in a substrate processing apparatus that includes: a processing container configured to be depressurized; a plasma box including an interior, which communicates with an interior of the processing container, and configured such that plasma is generated in the interior of the plasma box; a first gas nozzle installed in the processing container and into which a cleaning gas is introduced, and a second gas nozzle installed in the plasma box and configured such that an interior of the second gas nozzle is adjusted to have a negative pressure with respect to the interior of the processing container,
wherein the substrate processing method comprises:
removing deposits inside the plasma box by supplying the cleaning gas from the first gas nozzle into the processing container in a state in which the interior of the second gas nozzle is adjusted to have the negative pressure.

9. The substrate processing method of claim 8, wherein the substrate processing apparatus further includes a third gas nozzle installed inside the processing container and into which the cleaning gas is introduced, the third gas nozzle having an opening configured to eject gas upward, and
wherein the substrate processing method further comprises:
removing deposits inside the processing container by supplying the cleaning gas from at least one of the first gas nozzle, the second gas nozzle, or the third gas nozzle without adjusting the interior of the second gas nozzle to have the negative pressure with respect to the interior of the processing container.

10. The substrate processing method of claim 9, further comprising:
forming a film on a substrate by supplying a first reaction gas from the first gas nozzle and supplying a second reaction gas that reacts with the first reaction gas from the second gas nozzle in a state in which the substrate is accommodated in the processing container.

11. The substrate processing method of claim 10, wherein after performing the forming of the film a set number of times, the removing of the deposits inside the plasma box and the removing of the deposits inside the processing container are performed in this order.

12. The substrate processing method of claim 10, wherein after performing the forming of the film a first number of times, the removing of the deposits inside the plasma box is performed, and after performing the removing of the deposits inside the plasma box a second number of times, the removing of the deposits inside the processing container is performed.

13. The substrate processing method of claim 8, further comprising:
forming a film on a substrate by supplying a first reaction gas from the first gas nozzle and supplying a second reaction gas that reacts with the first reaction gas from the second gas nozzle in a state in which the substrate is accommodated in the processing container.

14. The substrate processing method of claim 13, wherein after performing the forming of the film a set number of times, the removing of the deposits inside the plasma box and the removing of the deposits inside the processing container are performed in this order.

15. The substrate processing method of claim 13, wherein after performing the forming of the film a first number of times, the removing of the deposits inside the plasma box is performed, and after performing the removing of the deposits inside the plasma box a second number of times, the removing of the deposits inside the processing container is performed.
